(19) United States
(12) Patent Application Publication
(10) Pub. No.: US 2026/0372118 A1
(43) Pub. Date: Nov. 19, 2026

(54) Semiconductor Device and Method of Making Having a Glass Substrate

(71) Applicant: STATS ChipPAC Management Pte. Ltd., Singapore (SG)

(72) Inventors: JinHee Jung, Incheon (KR); HeeSoo Lee, Incheon (KR); EunHee Myung, Gyeonggi-do (KR)

(73) Assignee: STATS ChipPAC Management Pte. Ltd., Singapore (SG)

(21) Appl. No.: 19/208,208

(22) Filed: May 14, 2025

(51) Int. Cl. H10W 70/05; H10P 54/00; H10W 70/60; H10W 70/685; H10W 70/692; H10W 74/01; H10W 90/00

(52) U.S. Cl. CPC H10W 70/05; H10W 70/095; H10W 70/685; H10W 70/692; H10W 74/016; H10P 54/00; H10W 70/60; H10W 90/724

(57) ABSTRACT

A semiconductor device has a first carrier. A first glass substrate is mounted to a first side of the first carrier. A second glass substrate is mounted to a second side of the first carrier. A first conductive layer is formed over the first glass substrate. A second conductive layer is formed over the second glass substrate. A second carrier is mounted to the first glass substrate over the first conductive layer. A third carrier is mounted to the second glass substrate over the second conductive layer. The first glass substrate and second glass substrate are removed from the first carrier. A third conductive layer is formed over the first glass substrate opposite the first conductive layer. A fourth conductive layer is formed over the second glass substrate opposite the second conductive layer. The second carrier is removed. The third carrier is removed.

### FIELD OF THE INVENTION

The present invention relates in general to semiconductor devices and, more particularly, to semiconductor devices and methods of making having a glass substrate.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor packages are sometimes formed using glass substrates. Glass substrates have good electrical performance due to low dielectric loss and high thermal stability. Glass substrates also have good planarity and allow for higher speed transmission and higher power-handling capabilities relative to organic substrates. However, handling of glass substrates during the manufacturing process is difficult. Breaking of glass during processing remains a significant problem. Therefore, a need exists for improved semiconductor devices and methods of making having glass substrates.

### BRIEF DESCRIPTION OF THE DRAWINGS

FIGS. 1a-1c illustrate a semiconductor wafer with a plurality of semiconductor die separated by a saw street;

FIGS. 2a-2p illustrate a process of forming a glass substrate;

FIGS. 3a-3d illustrate an alternative process flow; and

FIGS. 4a-4c illustrate an electronic device with a semiconductor package formed using the substrate.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

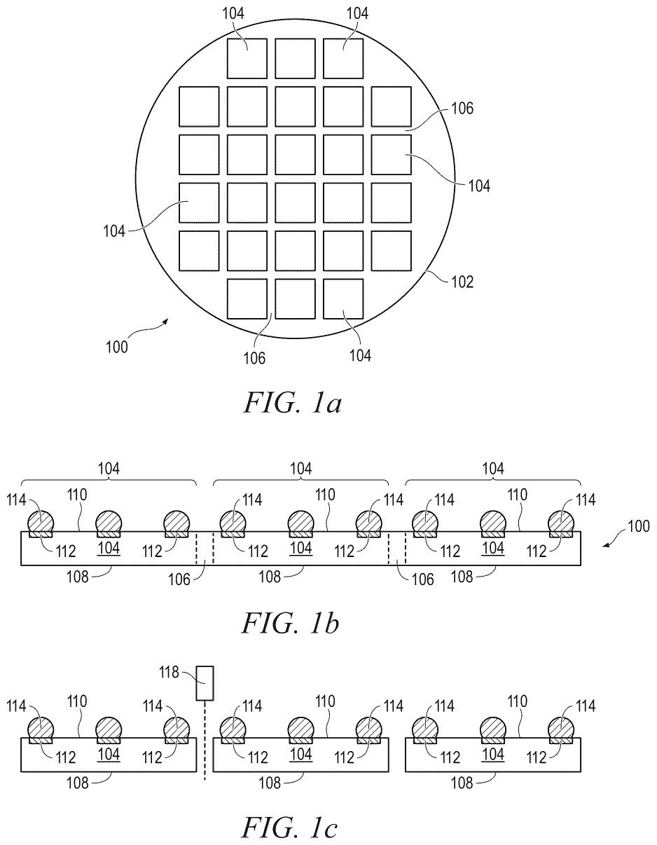

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bumps, micro bumps, or another type of electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

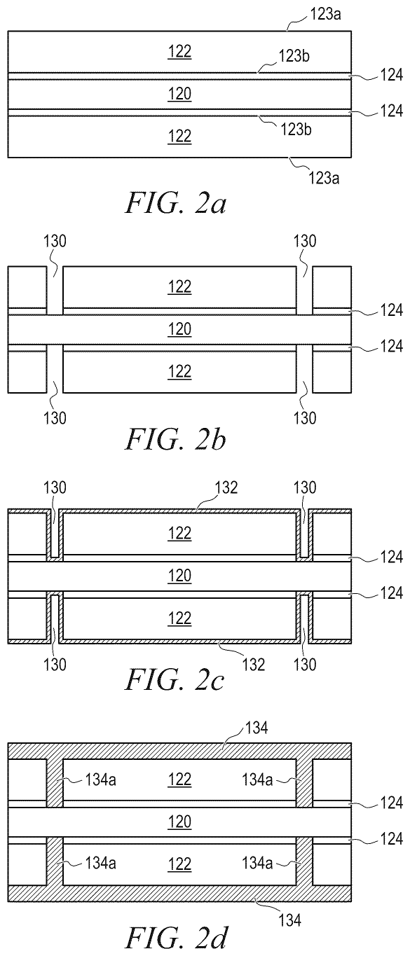

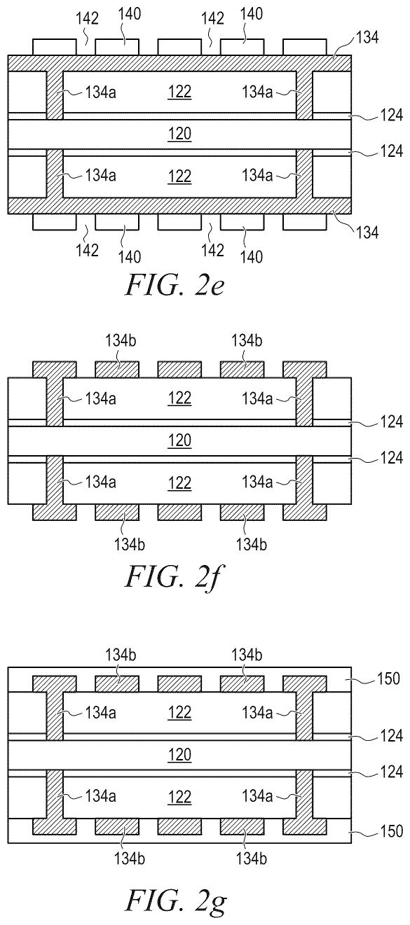

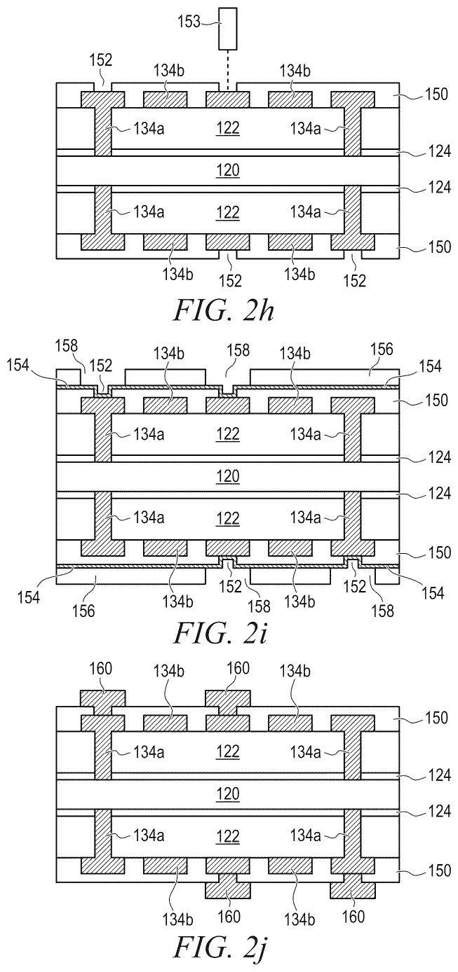

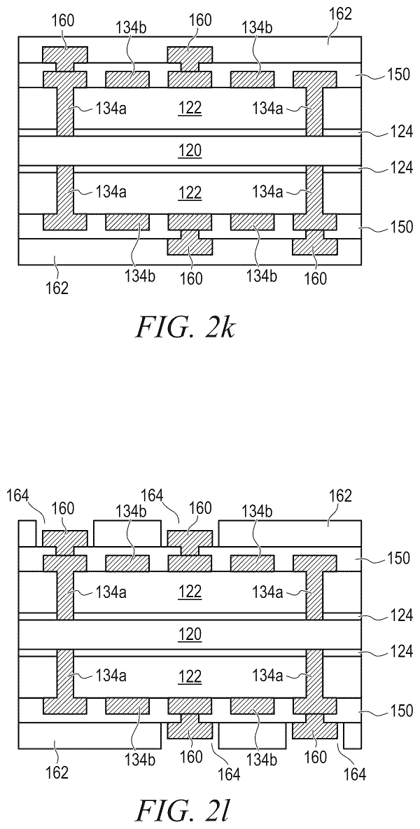

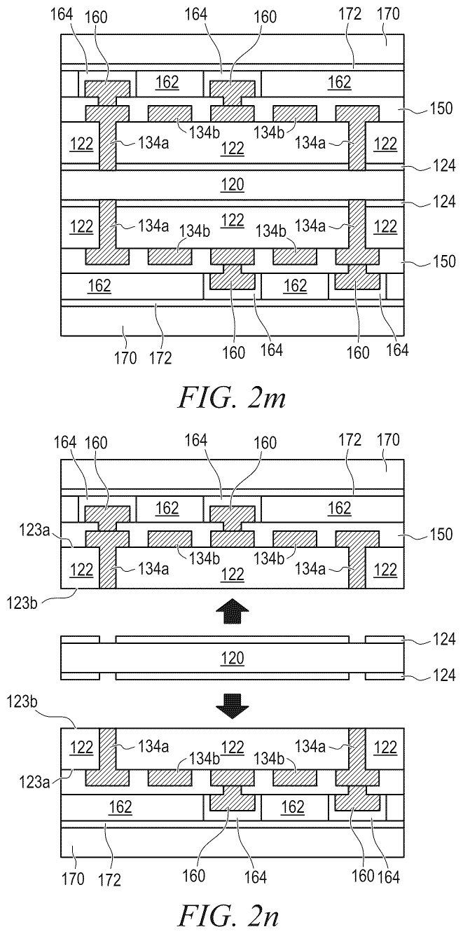

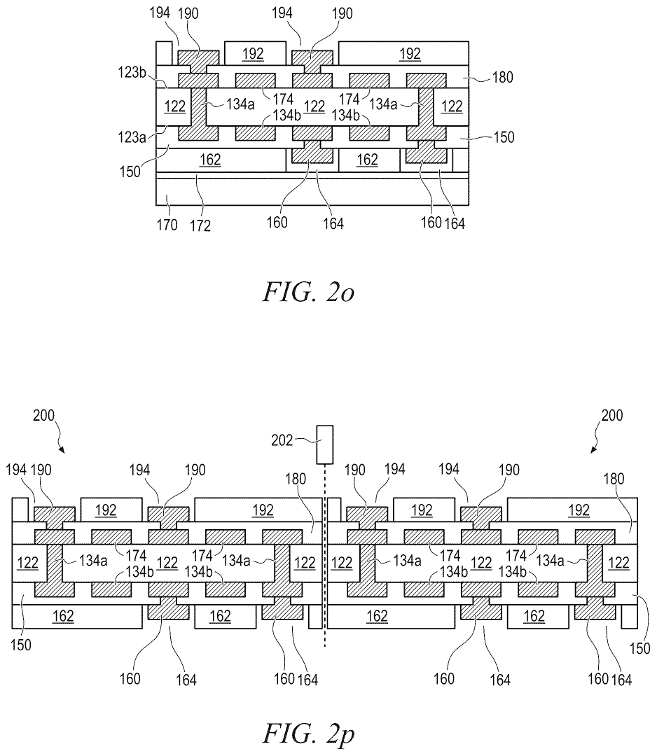

FIGS. 2a-2p illustrate a process of forming a glass interposer or substrate, which can then be used as a substrate to package semiconductor die 104 or for other purposes. The process begins in FIG. 2a, showing a carrier 120. Carrier 120 contains sacrificial base material such as silicon, polymer, beryllium oxide, glass, or other suitable low-cost, rigid material for structural support. Carrier 120 has two major surfaces, on the top and on the bottom in FIG. 2a, that will be processed either in parallel or sequentially, to form a glass substrate on both sides.

The steps shown below are shown as being performed together on both sides of carrier 120 at the same time. Each individual step can be performed on both sides at the same time, or on one side and then the other. In other embodiments, all the steps are performed on one side and then all the steps are performed on the other side. The steps can be performed on the two sides in any suitable order or grouping. The processing on both sides of carrier 120 is identical, as far as materials used and processes performed, to form two identical structures on the two sides of the carrier. In other embodiments, only one structure is formed on a single side of carrier 120, or two non-identical structures are formed on the two sides of the carrier.

Glass substrates 122 are attached to the top and bottom surfaces of carrier 120 using adhesive layers 124 as a temporary adhesive bonding film, etch-stop layer, thermal release layer, or UV release layer. Glass substrates 122 are formed of, e.g., sheets of Corning glass. Glass substrates 122 are made of a high-purity borosilicate or aluminosilicate glass designed for semiconductor manufacturing. In one embodiment, glass substrate 122 comprises 60-80 per cent by weight of SiO₂, 5-20 per cent by weight of B₂O₃ or Al₂O₃, and 2 percent or less by weight of alkali oxides. Glass substrate 122 has low impurity levels (<10 ppm) and alkali content (<0.1 per cent by weight). Glass substrate 122 is formed via a float glass or fusion draw process.

In one embodiment, glass substrate 122 has a thickness of 0.3 mm to 1.1 mm, surface roughness (Ra) less than 0.5 nm, and a flatness of less than 1 μm bow/warp over 300 mm. Annealing at 500-700 °C and polishing with cerium oxide yields defect-free primary surfaces 123a and 123b compatible with nanoscale deposition. Glass substrate 122 exhibits a low coefficient of thermal expansion (~3.0-4.5×10⁻⁶/°C), high transparency (>90% at 300-800 nm), and thermal stability up to 600 °C, making it ideal for advanced semiconductor processes, including thin-film deposition and EUV lithography.

Glass substrates 122 are formed with two identical major surfaces 123a and 123b. The surfaces are arbitrarily designated with surfaces 123a oriented away from carrier 120 for processing. Through-glass vias (TGVs) 130 are formed through glass substrate 122 in FIG. 2b from surface 123a to surface 123b. TGVs 130 are formed in glass substrate 122 using a laser drilling process to enable vertical electrical interconnects. In one embodiment, the process employs a pulsed ultraviolet (UV) laser, typically a nanosecond or picosecond laser with a wavelength of 248-355 nm, delivering pulse energies of 100-500 μJ at a repetition rate of 10-100 kHz. The laser is focused on the substrate surface, ablating material to create vias with diameters of 10-50 μm and depths matching the substrate thickness. In other embodiments, TGVs 130 are formed by wet-etching, mechanical drilling, deep reactive ion etching (DRIE) or another suitable process.

Interface layer 124 can be fully removed, partially removed, or not removed at all by the TGV 130 formation process. Post-drilling, TGVs 130 are cleaned with a brief ultrasonic rinse in deionized water to remove residual ablation products, achieving smooth sidewalls with roughness (Ra) less than 50 nm and taper angles of 85-90°. The resulting TGVs 130 provide high-aspect-ratio interconnect pathways, enabling reliable metallization and integration.

In FIG. 2c, a seed layer 132 is formed over glass substrate 122 by electroless plating, sputtering, or another suitable process. Seed layer 132 completely covers a top surface of glass substrate 122 and internal surfaces of TGVs 130. In one embodiment, seed layer 132 is deposited as a bilayer, with a 10-30 nm titanium (Ti) or chromium (Cr) adhesion layer applied via DC magnetron sputtering to ensure robust bonding to glass substrate 122, followed by a 50-200 nm copper (Cu) or nickel (Ni) conductive layer using the same PVD system at a 0.5 nm/s deposition rate. To achieve conformal coverage within high-aspect-ratio TGVs 130, the substrate is rotated at 10 rpm during sputtering, and a collimated sputter source directs metal atoms into the vias. This method ensures a uniform and adherent seed layer 132 over glass substrate 122 and into TGVs 130.

A conductive layer 134 is formed over seed layer 132 in FIG. 2d. Conductive layer 134 is formed using materials and methods described above for conductive layer 112. Conductive layer 134 completely covers a top surface of glass substrate 122 and fills TGVs 130 to form conductive vias 134a. Seed layer 132 and conductive layer 134 are drawn collapsed into a single conductive layer to simplify illustration, although seed layer 132 remains under conductive layer 134 in practice. Conductive layer 134 can be polished by etching, chemical mechanical planarization (CMP), grinding, or other suitable means to reach or maintain a desired thickness.

A mask layer 140 is formed over conductive layer 134 in FIG. 2e. Mask layer 140 comprises a photoresist material such as a positive-tone dry film photoresist, liquid photoresist, or another suitable material. Photoresist layer 140 is exposed to ultraviolet (UV) light through a photolithographic mask defining pattern 142. Pattern 142 corresponds to regions where conductive layer 134 will be removed to pattern conductive layer 140. Post-exposure, the photoresist is developed, selectively removing the exposed regions to form etched pattern 142 in mask layer 140. Another type of photoresist is used in other embodiments

The exposed conductive layer 134 within pattern 142 is then etched, e.g., using a wet etching process with a copper etchant, selectively removing copper until the underlying seed layer 132 or glass substrate 122 is exposed. The remaining photoresist of mask layer 140 is stripped in FIG. 2f to leave contact pads 134b patterned on the external surfaces of glass substrates 122. In some embodiments, conductive layer 134 also includes conductive traces to fan-out interconnection from conductive vias 134a to contact pads 134b. Any remaining portions of seed layer 132 outside of the footprint of conductive layer 134 is removed in a separate etching step if necessary.

In FIG. 2g, an insulating layer 150 is formed over conductive layer 134. Insulating layer 150 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Any insulating layer mentioned herein can be formed using the same materials and methods described for insulating layer 150. Insulating layer 150 is a laminated Ajinomoto Build-up Film (ABF) layer in one embodiment. Openings 152 are formed through insulating layer 150 in FIG. 2h by laser ablation using laser 153 or another suitable process. Openings 152 expose contact pads 134b for subsequent electrical interconnect.

FIG. 2i shows a seed layer 154 formed over insulating layer 150 and into openings 152 to physically and electrically couple to contact pads 134b. Seed layer 154 is formed as described above for seed layer 132. A mask layer 156 is formed over seed layer 154. Mask layer 156 can be the same or different from mask layer 140 used above. Openings 158 are formed in mask layer 156 as described above for pattern 142 formed in mask layer 140, e.g., by photolithography, or another suitable process. Openings 158 are configured to allow contact or under-bump metallization (UBM) pads 160 to be formed in FIG. 2j before removing mask layer 156 and etching seed layer 154 around the contact pads. Seed layer 154 remains under contact pads 160, but, as above, the two layers are drawn as being collapsed into one for ease of illustration.

While a semi-additive process is used to form contact pads 160 and a subtractive process is used to form conductive layer 134, any suitable process can be used to form the two conductive layers, including using the same process for both conductive layers. An optional passivation layer can be formed over insulating layer 150.

A solder resist layer 162 is laminated over contact pads 160 in FIG. 2k. Solder resist layer 162 is a protective insulating film formed from materials such as liquid photoimageable solder masks (PSMs), dry film solder resists, non-photoimageable epoxy films, epoxy-based films, or epoxy-acrylate blends. In other embodiments, solder resist layer 162 can be formed using any of the materials and processes described above for other insulating layers.

Openings 164 are formed through solder resist layer 162 in FIG. 2l to expose contact pads 160. Openings 164 are larger than contact pads 160 such that side surfaces of the contact pads are exposed within the openings around an entire perimeter of each contact pad. Openings 164 are formed by laser ablation, chemical etching, photolithography, or another suitable process based on the type of material used for solder resist 162.

In FIG. 2m, a pair of second carriers 170 are mounted onto solder resist layers 162 using interface layers 172. Carriers 170 and interface layers 172 can be any of the options described above for carrier 120 and interface layer 122, respectively. Carrier 120 is separated from the overlying and underlying structures in FIG. 2n to leave two separate and identical structures supported by two separate carriers 170 instead of a single centrally located carrier 120. Carrier 120 is removed by thermal release or another suitable mechanism based on the particular interface layer 124 material used. The removal of carrier 120 exposes surfaces 123b of glass substrates 122 for further processing.

In FIG. 2o, surfaces 123b of glass substrates 122 are processed to add interconnects matching the previously formed conductive layer 134 and contact pads 160. Conductive layer 174 is formed on glass substrate 122 as described above for conductive layer 134, including the use of a seed layer as desired. Conductive layer 174 includes contact pads on conductive vias 134a, and optionally conductive traces to fan-out the connections from the vias. A different formation method may be desired for conductive layer 174 due to there being no need to also form conductive vias through glass substrate 122. Both sides separated from carrier 120 in FIG. 2n are separately processed in the same manner.

Insulating layer 180 is formed over conductive layer 174 as described above for insulating layer 150. Contact pads or UBM pads 190 are formed over insulating layer 180 and through openings in the insulating layer to physically and electrically contact conductive layer 174 as described above for contact pads 160, including the use of a seed layer if desired. A solder resist layer 192 is formed over contact pads 190 with openings 194 formed through the solder resist layer as described above for solder resist layer 162 and openings 164 over contact pads 160.

In some embodiments, a panel of the units shown in FIG. 2o is formed together and then singulated by a saw, a laser cutting tool 202, or another suitable means in FIG. 2p to finish glass substrate modules 200. Carrier 170 is removed before or after singulation. Alternatively, substrate modules 200 can remain attached as a panel until after semiconductor packages are subsequently formed on the substrate modules. Substrate modules 200 include a glass substrate 122 with matching or corresponding interconnect on both sides of the glass substrate. The interconnect provided by conductive layers 174 can be exactly the same as the interconnect provided by conductive layer 134 or different. In either case, the general structure of both sides of glass substrate 122 is the same.

Carrier 120 is used to form substrate module 200, which protects glass substrate 122 from potential damage. One side of glass substrate 122, with conductive layer 134, is processed while the glass substrate is supported by carrier 120. The second side of glass substrate 122, with conductive layer 174, is then processed with the second substrate 170 supporting glass substrate 122. Glass substrates 122 are protected by either carrier 120 or 170 during all processing steps. Processing the first side of two different glass substrate 122 at one time supported by a single carrier 120 streamlines processing to increase productivity. Glass substrate 122 has surfaces with low roughness, similar to that of a silicon substrate, thus allowing fine patterning.

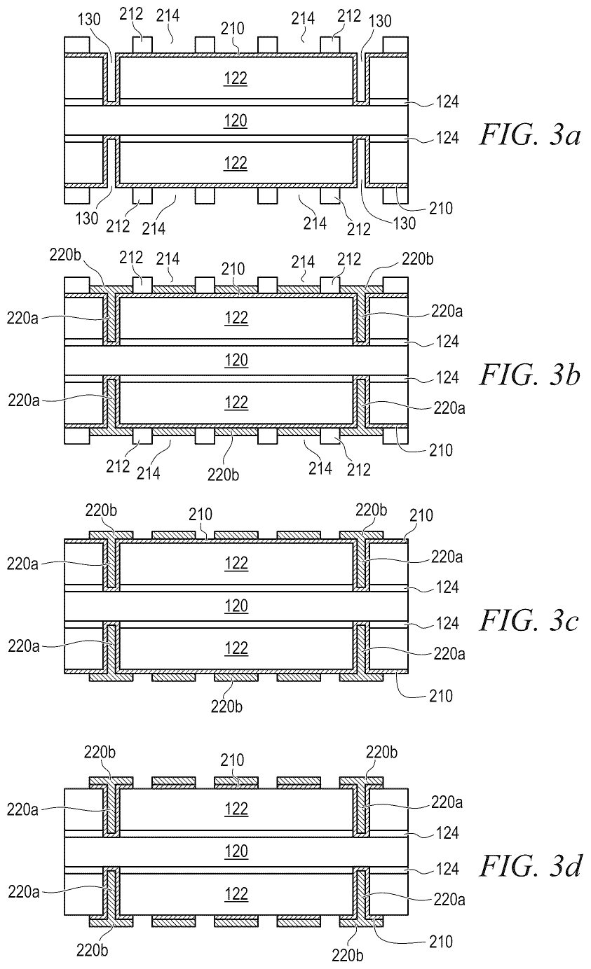

FIGS. 3a-3d illustrate an alternative embodiment where a semi-additive process is used to form the first conductive layer through and over glass substrates 122. FIG. 3a continues from FIG. 2b after forming TGVs 130.A seed layer 210 is formed over glass substrates 122 and into TGVs 130. Seed layer 210 can be formed using the processes and materials described above for seed layer 132, or another process and material can be used if more suitable for the semi-additive process. A mask layer 212 is formed over and on seed layer 210, with a pattern 214 formed in the mask layer to define the conductive layer being formed. Mask layer 212 can be formed using the same materials and methods described above for mask layers 140 and 156.

Conductive layer 220 is formed over seed layer 210 in pattern 214 in FIG. 3b. Conductive layer 220 includes contact pads 220b formed on the top surface of glass substrate 122 and conductive vias 220a formed in TGVs 130. Conductive layer 220 can be formed using any of the methods and materials described above for other conductive layers, e.g., by electroplating copper. Mask layer 212 is removed in FIG. 3c to leave conductive layer 220 as islands on seed layer 210. Seed layer 210 is etched in FIG. 3d using conductive layer 220 as a mask to leave conductive layer 220 and seed layer 210 in the desired pattern ready for further processing. Manufacturing continues as shown in FIGS. 2g-2p to complete substrate modules with glass substrates 122.

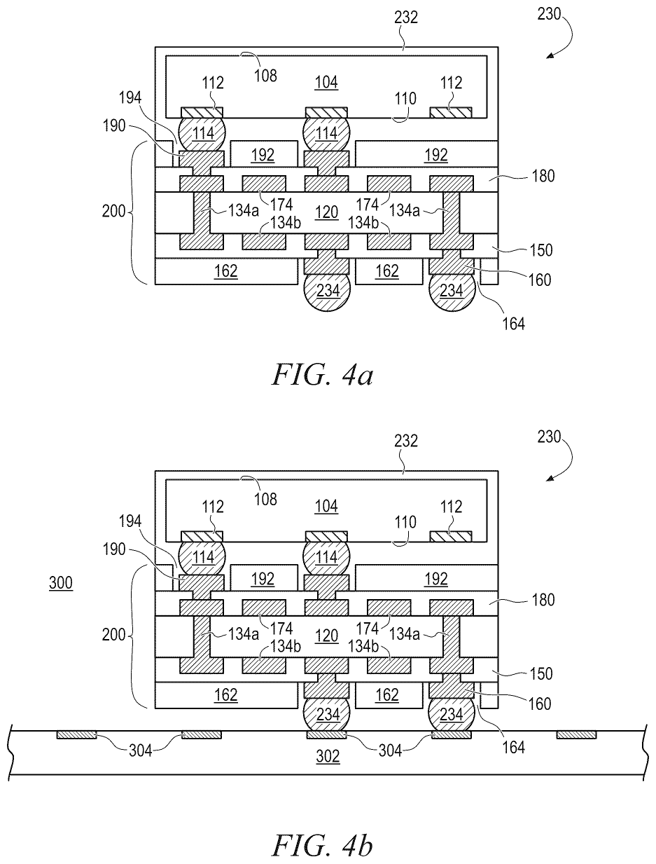

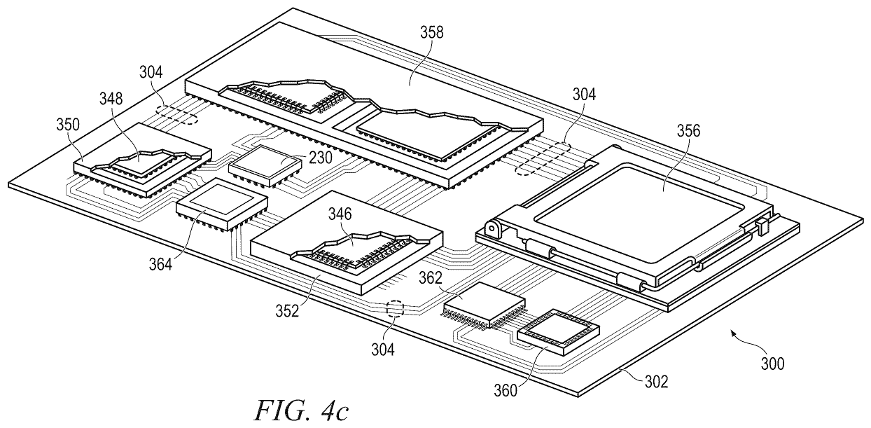

FIGS. 4a-4c illustrate a semiconductor package with a substrate module 200 incorporated into a larger electronic device. The above-described substrate modules can be used to form semiconductor packages in any desired configuration. FIG. 4a shows one example with semiconductor die 104 mounted onto substrate module 200. An encapsulant or molding compound 232 is deposited over substrate module 200 and semiconductor die 104. Encapsulant 232 is deposited using a paste printing, compression molding, transfer molding, liquid encapsulant molding, vacuum lamination, spin coating, or other suitable applicator. Encapsulant 232 can be liquid or granular polymer composite material, such as epoxy resin, epoxy acrylate, or another suitable polymer, with or without a filler. Encapsulant 232 is non-conductive, provides structural support, and environmentally protects the embedded electrical components from external elements and contaminants. Semiconductor package 230 can be formed by mounting semiconductor die 104 and depositing encapsulant 232 prior to singulation in FIG. 2p. Solder bumps 234 are formed on contact pads 134b as described above for bumps 114 on conductive layer 112.

FIGS. 4b and 4c illustrate integrating the above-described semiconductor packages, e.g., package 230, into a larger electronic device 300. FIG. 4b illustrates a partial cross-section of package 230 mounted onto a printed circuit board (PCB) or other substrate 302 as part of electronic device 300. Solder bumps 234 are reflowed onto conductive layer 304 of PCB 302 to physically attach and electrically connect package 230 to the PCB. In other embodiments, thermocompression or another suitable attachment and connection methods are used. In some embodiments, an adhesive or underfill layer is used between package 230 and PCB 302. Semiconductor die 104 are electrically coupled to conductive layer 304 through substrate module 200.

FIG. 4c illustrates electronic device 300 having a chip carrier substrate or PCB 302 with a plurality of semiconductor packages disposed on a surface of PCB 302, including package 230. Electronic device 300 can have one type of semiconductor package, or multiple types of semiconductor packages, depending on the application. In other embodiments, package 230 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 4c, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first carrier;
mounting a first glass substrate to a first side of the first carrier;
mounting a second glass substrate to a second side of the first carrier;
forming a first conductive layer over the first glass substrate;
forming a second conductive layer over the second glass substrate;
mounting a second carrier to the first glass substrate over the first conductive layer;
mounting a third carrier to the second glass substrate over the second conductive layer;
removing the first glass substrate and second glass substrate from the first carrier;
forming a third conductive layer over the first glass substrate opposite the first conductive layer;
forming a fourth conductive layer over the second glass substrate opposite the second conductive layer;
removing the second carrier; and
removing the third carrier.

2. The method of claim 1, further including forming the first conductive layer, second conductive layer, third conductive layer, and fourth conductive layer using a semi-additive process.

3. The method of claim 1, further including forming the first conductive layer, second conductive layer, third conductive layer, and fourth conductive layer using a subtractive process.

4. The method of claim 3, further including forming contact pads over the first conductive layer, second conductive layer, third conductive layer, and fourth conductive layer using a semi-additive process.

5. The method of claim 4, further including mounting a semiconductor die to the contact pads.

6. The method of claim 1, further including:
forming a plurality of through-glass vias through the first glass substrate and second glass substrate; and
forming the first conductive layer and second conductive layer into the through-glass vias.

7. A method of making a semiconductor device, comprising:
providing a first carrier;
mounting a first glass substrate to a first side of the first carrier;
mounting a second glass substrate to a second side of the first carrier;
forming a first conductive layer over the first glass substrate;
forming a second conductive layer over the second glass substrate;
mounting a second carrier to the first glass substrate over the first conductive layer;
mounting a third carrier to the second glass substrate over the second conductive layer; and
removing the first glass substrate and second glass substrate from the first carrier.

8. The method of claim 7, further including forming the first conductive layer and second conductive layer using a semi-additive process.

9. The method of claim 7, further including forming the first conductive layer and second conductive layer using a subtractive process.

10. The method of claim 9, further including forming contact pads over the first conductive layer and second conductive layer using a semi-additive process.

11. The method of claim 10, further including mounting a semiconductor die to the contact pads.

12. The method of claim 11, further including depositing an encapsulant over the semiconductor die.

13. The method of claim 7, further including:
forming a plurality of through-glass vias through the first glass substrate and second glass substrate; and
forming the first conductive layer and second conductive layer into the through-glass vias.

14. A method of making a semiconductor device, comprising:
providing a first carrier;
mounting a glass substrate to a first side of the first carrier;
forming a first conductive layer over the first glass substrate;
mounting a second carrier to the first glass substrate over the first conductive layer; and
removing the first glass substrate and second carrier from the first carrier.

15. The method of claim 14, further including forming the first conductive layer using a semi-additive process.

16. The method of claim 14, further including:
forming a plurality of through-glass vias through the first glass substrate; and
forming the first conductive layer into the through-glass vias.

17. The method of claim 14, further including forming the first conductive layer using a subtractive process.

18. The method of claim 17, further including forming contact pads over the first conductive layer using a semi-additive process.

19. The method of claim 18, further including mounting a semiconductor die to the contact pads.

20. The method of claim 19, further including depositing an encapsulant over the semiconductor die.

21. A semiconductor device, comprising:
a first carrier;
a first glass substrate mounted to a first surface of the first carrier;
a second glass substrate mounted to a second surface of the first carrier;
a first conductive layer formed over the first glass substrate;
a second conductive layer formed over the second glass substrate;
a second carrier disposed over the first conductive layer; and
a third carrier disposed over the second conductive layer.

22. The semiconductor device of claim 21, wherein the first conductive layer includes a plurality of conductive vias extending through the first glass substrate.

23. The semiconductor device of claim 21, further including a contact pad formed on the first conductive layer under the second carrier.

24. The semiconductor device of claim 21, further including a first releasable adhesive layer disposed between the first carrier and first glass substrate.

25. The semiconductor device of claim 24, further including a second releasable adhesive layer disposed between the second carrier and first glass substrate.
